(19) United States
(12) Patent Application Publication
(10) Pub. No.: US 2016/0322376 A1
(43) Pub. Date: Nov. 3, 2016

(54) THREE-DIMENSIONAL SEMICONDUCTOR DEVICE

(71) Applicant: SK hynix Inc., Gyeonggi-do (KR)

(72) Inventor: Sang Bum LEE, Incheon (KR)

(21) Appl. No.: 14/874,139

(22) Filed: Oct. 2, 2015

(30) Foreign Application Priority Data
Apr. 29, 2015 (KR) 10-2015-0060526

(51) Int. Cl. H01L 27/115

(52) U.S. Cl. CPC H01L 27/11573; H01L 27/1158

(57) ABSTRACT

Disclosed is a three-dimensional semiconductor device, including: a peripheral circuit; a memory cell array stacked on the peripheral circuit and including a memory region and a slimming region which are defined in a first direction, wherein the slimming region includes contact regions and step regions alternately defined in the first direction, wherein the slimming region further includes pad regions defined in a second direction orthogonal to the first direction, wherein the pad regions overlap with some of the contact regions and some of the step regions, wherein gate lines are included in the step regions and arranged in a step form in the first direction, and wherein gate lines are included in a region in which the contact regions, the step regions, and the pad regions overlap each other and have steps in the second direction.

### CROSS-REFERENCE TO RELATED APPLICATIONS

The present application claims priority to Korean patent application number 10-2015-0060526 filed on Apr. 29, 2015, the entire disclosure of which is herein incorporated by reference.

### BACKGROUND

1. Field

The present application relates to a three-dimensional semiconductor device, and more particularly, to a three-dimensional semiconductor device including a slimming region.

2. Discussion of Related Art

A semiconductor device includes a memory device in which data is stored. A memory cell array includes a plurality of memory blocks. The memory blocks may be formed in a two-dimensional or three-dimensional structure. The memory blocks of the two-dimensional structure include memory cells arranged in a direction parallel to an upper surface of a substrate, and the memory blocks of the three-dimensional structure include memory cells stacked in a vertical direction to a substrate.

The semiconductor device including the memory blocks of the three-dimensional structure may be called a three-dimensional semiconductor device. The memory block of the three-dimensional semiconductor device will be described in more detail. The memory block may include a plurality of cell strings arranged in a direction vertical to an upper surface of a substrate. The cell strings may include source select transistors, memory cells, and drain select transistors connected between bit lines and a source line. For example, the cell strings may include vertical channel layers, source select lines, word lines, and drain select lines. The source select lines, the word lines, and drain select lines are stacked while being spaced apart from each other. The stack of the source select lines, the word lines, and drain select lines surrounds each of the vertical channel layers. The source select so transistors may be formed between the vertical channel layers and the source select lines. The memory cells may be formed between the vertical channel layers and the word lines. The drain select transistors may be formed between the vertical channel layers and the drain select lines.

The semiconductor device includes a peripheral circuit for performing a program operation, a read operation, or an erase operation of the aforementioned memory blocks and further includes a control circuit for controlling the peripheral circuit.

The peripheral circuit may include a voltage generating circuit, a row decoder, a page buffer unit, and a column decoder. The voltage generating circuit may generate operation voltages. The row decoder may transmit the operation voltages to source lines, word lines, and drain select lines connected to a selected memory block. The page buffer unit may transceive data with the selected memory block through the bit lines. The column decoder may transceive data through the page buffer unit or transceive data with an external device for example, a semiconductor control unit.

### SUMMARY

The present application has been made in an effort to provide a three-dimensional semiconductor device capable of reducing a size of a semiconductor device and simplifying a manufacturing process. An exemplary embodiment of the present application provides a three-dimensional semiconductor device, including: a peripheral circuit; a memory cell array stacked on the peripheral circuit and including a memory region and a slimming region which are defined in a first direction, wherein the slimming region includes contact regions and step regions alternately defined in the first direction, wherein the slimming region further includes pad regions defined in a second direction orthogonal to the first direction, wherein the pad regions overlap with some of the contact regions and some of the step regions, wherein gate lines are included in the step regions and arranged in a step form in the first direction, and wherein gate lines are included in a region in which the contact regions, the step regions, and the pad regions overlap each other and have steps in the second direction.

An exemplary embodiment of the present application provides a three-dimensional semiconductor device, including: a row decoder; and a memory cell array including source select lines, word lines, and drain select lines, wherein the source select lines, the word lines, and the drain select lines are sequentially stacked over the row decoder, wherein a first slimming region, a memory region, and a second slimming region are defined in the memory cell array in a first direction, wherein the source select lines are connected to the row decoder through first contact plugs formed in the first slimming region, and wherein the word lines and the drain select lines are connected to the row decoder through second contact plugs and third contact plugs formed in the second slimming region, respectively.

According to the exemplary embodiment of the present application, it is possible to decrease a size of a semiconductor device, and simplify a manufacturing cost to reduce manufacturing cost.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present application will become more apparent to those of ordinary skill in the art by describing in detail embodiments thereof with reference to the attached drawings in which:

FIG. 1 is a perspective view illustrating a semiconductor device according to an exemplary embodiment of the present application;

FIG. 2 is a plan view illustrating a disposition of a peripheral circuit of FIG. 1 in detail;

FIG. 3 is a perspective view illustrating a memory block of FIG. 2 in detail;

FIG. 4 is a perspective view schematically illustrating a connection relation between the memory block and the peripheral circuit according to the exemplary embodiment of the present application;

FIG. 5 is a perspective view illustrating a first slimming region shown in FIG. 4;

FIG. 6 is a perspective view illustrating a second slimming region shown in FIG. 4;

FIGS. 7 to 10 are perspective views illustrating a method of forming the first slimming region and the second slimming region according to the exemplary embodiment of the present application;

FIG. 11 is a perspective view illustrating a connection relation between drain select lines and a row decoder according to the exemplary embodiment of the present application;

FIGS. 12 and 13 are perspective views illustrating a connection relation between word lines and the row decoder according to the exemplary embodiment of the present application;

FIG. 14 is a perspective view illustrating a connection relation between source select lines and the row decoder according to the exemplary embodiment of the present application;

FIG. 15 is a block diagram illustrating a solid state drive including the semiconductor device according to the exemplary embodiment of the present application;

FIG. 16 is a block diagram illustrating a memory system including the semiconductor device according to the exemplary embodiment of the present application; and

FIG. 17 is a diagram illustrating a schematic configuration of a computing system including the semiconductor device according to the exemplary embodiment of the present application.

### DETAILED DESCRIPTION

Hereinafter, an exemplary embodiment of the present application will be described in detail with reference to the accompanying drawings. However, the present application is not limited to embodiments disclosed below, but various forms different from each other may be implemented. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

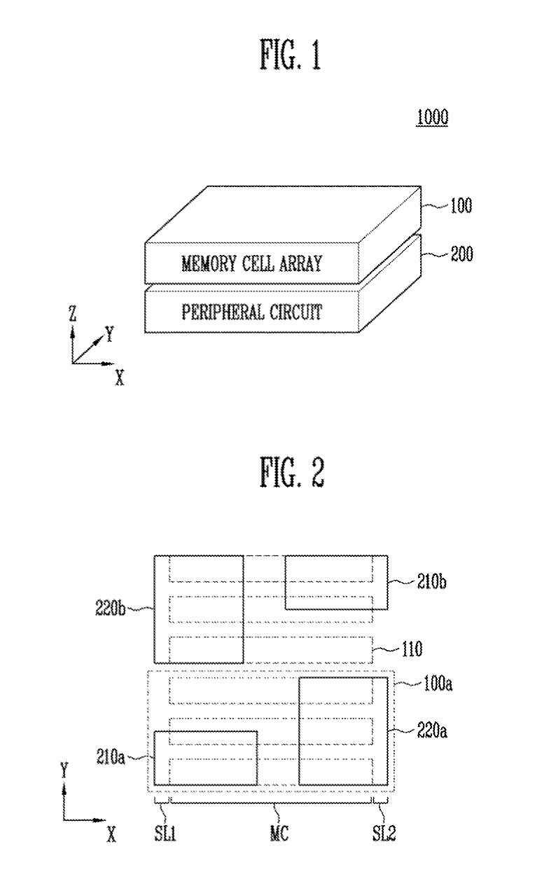

FIG. 1 is a perspective view illustrating a semiconductor device according to an exemplary embodiment of the present application. Referring to FIG. 1, a semiconductor device 1000 may include a memory cell array 110 in which data is stored and a peripheral circuit 200 configured to perform a program operation, a read operation, or an erase operation of the memory cell array 100. Although not illustrated in FIG. 1, a control circuit (not illustrated) controlling the peripheral circuit 200 may be further included.

The peripheral circuit 200 may include a plurality of circuits, which may decrease a size of the semiconductor device 1000, some of the circuits included in the peripheral circuit 200 may be disposed under the memory cell array 100.

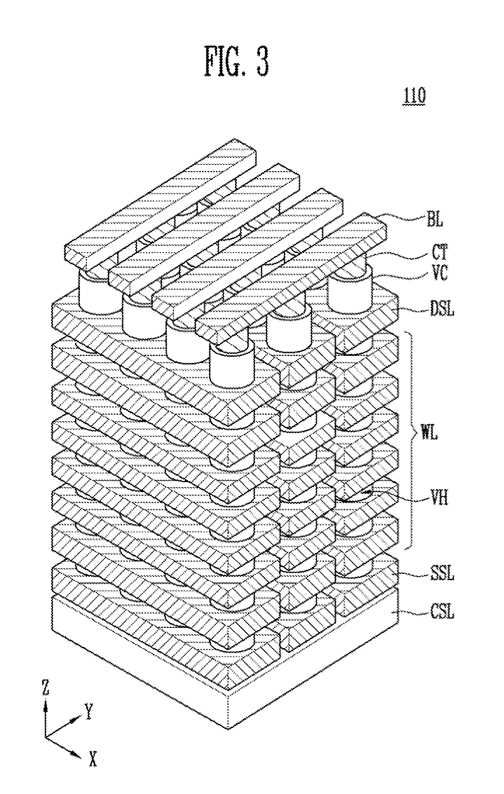

FIG. 2 is a plan view illustrating a disposition of the peripheral circuit of FIG. 1 in detail. Referring to FIG. 2, the peripheral circuit 200 may include a plurality of circuits. For example, the peripheral circuit 200 may include a voltage generating circuit (not illustrated), row decoders 220a and 220b, page buffer units 210a and 210b, and a column decoder (not illustrated). Among them, the row decoders 220a and 220b and the page buffer units 210a and 210b may be disposed under the memory cell array 100.

The memory cell array 100 may include a plurality of memory blocks 110. Each of the row decoders 220a and 220b and page buffer units 210a and 210b may be divided into a plurality of circuit units for connection with the memory blocks 110. For example, the row decoders 220a and 220b may include a first row decoder 220a and a second row decoder 220b, and the age buffer units 210a and 210b may include a first page buffer unit 210a and a second page buffer unit 210b.

The first page buffer unit 210a may be connected to the memory blocks 110 through some of the bit lines (not illustrated). The second page buffer 210b may be connected to the memory blocks 110 through the remaining bit lines (not illustrated) which are not connected to the first page buffer unit 210a.

The first row decoder 220a may be connected to some of the memory blocks 110, and the second row decoder 220b may be so connected to the remaining memory blocks which are not connected to the first row decoder 220a.

In order to connect the three-dimensional memory blocks 110 with the row decoders 220a and 220b, first and second slimming regions SL1 and SL2 are defined at both ends of the memory blocks. In the first and the second slimming regions SL1 and SL2, the source select lines, the word lines, and the drain select lines extend in a step form. The region in which the memory blocks 110a are formed is defined as a memory region MC. The first slimming region SL1 is defined at one end of the memory region MC and the second slimming region SL2 is defined at the other end of the memory region MC.

The source select lines, the word lines, and the drain select lines extended in the first slimming region SL1 and the second slimming region SL2 may be connected to the row decoders 220a and 220b through contacts.

FIG. 3 is a perspective view illustrating the memory block of FIG. 2 in detail. Referring to FIG. 3, the memory block may include a source line CSL, vertical channel layers VC, source select lines SSL, word lines WL, drain select lines DSL, and bit lines BL.

The source line CSL may be formed on a substrate (not illustrated) having a plane in an X-Y direction, and disposed at the bottommost ends of the memory blocks 110. The vertical channel layers VC are arranged in a matrix form in an X-direction and a Y-direction. The vertical channel layers VC are formed on the source line CSL and extend in a Z-direction, Here, the X, Y, and Z directions are orthogonal to one another. The X and Y directions are in parallel to the substrate. The Z-direction is vertical to the substrate.

For example, the vertical channel layers VC may include circular channel layers and memory layers surrounding the channel layers. The channel layers may be formed of a doped polysilicon layer. The memory layers may include gate insulating layers surrounding the channel layers, charge trap layers surrounding the gate insulating layers, and blocking layers surrounding the charge trapping layers.

The source select lines SSL are positioned on the source line CSL, surround the vertical channel layers VC, are extended in the X-direction, and are spaced apart from each other in the Y-direction. The source select lines SSL may be formed of lines of a single layer or multiple layers.

The word lines WL are positioned on the source select lines SSL, surround the vertical channel layers VC, are extended in the X-direction, are spaced apart from each other in the Y-direction, and are stacked along the vertical channel layers VC while being spaced apart from each other in the Z-direction.

The drain select lines SSL are positioned on the word lines WL, surround the vertical channel layers VC, are extended in the X-direction, and are spaced apart from each other in the Y-direction. The drain select lines DSL may be formed of lines of a single layer or multiple layers.

The bit lines BL are extended in the Y-direction on the vertical channel layers VC protruding from upper portions of the drain select lines DSL and are spaced apart from each other in the X-direction. Contact plugs CT may be further formed between the bit lines BL and the vertical channel layers VC.

Although not illustrated, insulating layers may be formed between the source line CSL, the vertical channel layers VC, the source select lines SSL, the word lines WL, the drain select lines DSL, and the bit lines VL.

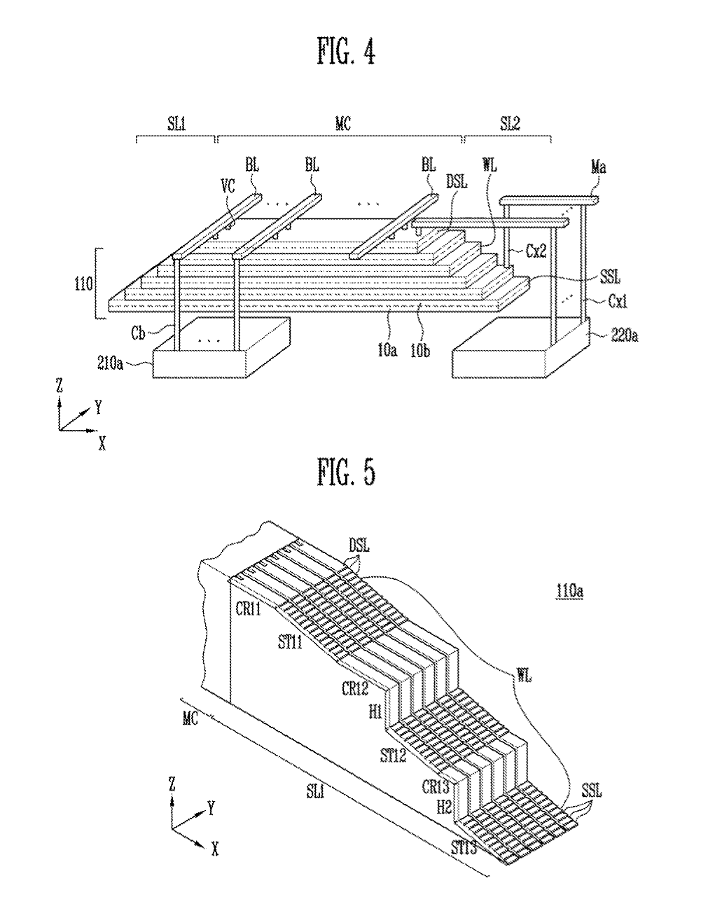

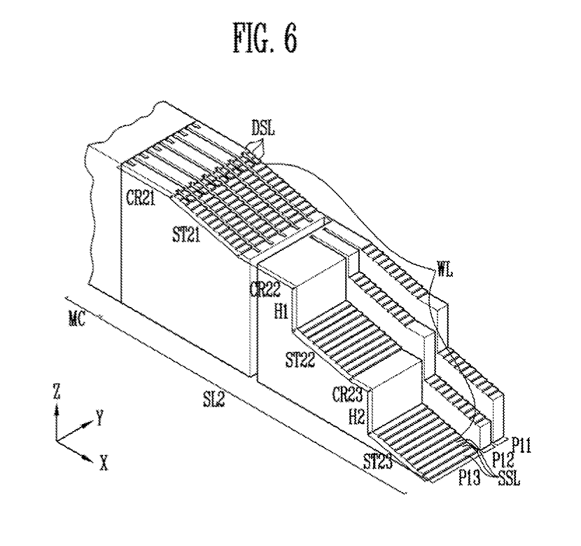

FIG. 4 is a perspective view schematically illustrating a connection relation between the memory block and the peripheral circuit according to the exemplary embodiment of the present application, and illustrates the region corresponding to reference numeral 100a of FIG. 2.

Referring to FIG. 4, among the lines CSL, SSL, WL, DSL, and BL included in the memory block 110, the source Sine CSL, the vertical channel layers VC the source select lines SSL, the word lines WL, and the drain select lines DSL which are located in the memory region MC and extend in the X-direction have step forms in the first slimming region SL1 and the second slimming region SL2. The bit lines BL are connected to the upper portions of the vertical channel layers VC arranged in the Y-direction within the memory region MC.

The source select lines SSL, the word lines WL, and the drain select lines DSL may be formed of conductive layers 10b, and insulating layers 10a may be formed between the respective lines. That is, as illustrated in FIG. 4, the conductive layers 10b forming the respective lines SSL, WL, and DSL and the insulating layers 10a are paired to form one layer. For example, FIG. 4 is a perspective view schematically illustrating a connection relation between the first and second slimming regions SL1 and SL2 and the first row decoder 220a, and a connection relation between the bit lines BL and the first page buffer unit 210a. A detailed structure, such as a spaced structure of the respective lines SSL, WL, and DSL, is omitted.

The first row decoder 220a transmits operation voltages through the first or second slimming region SL1 or SL2, or the lines SSL, WL, and DSL extended in the first and second slimming regions SL1 and SL2. To this end, first contact plugs Cx1 are formed on the first row decoder 220a, second contact plugs Cx2 are formed on the lines SSL, WL, and DSL exposed in a step structure in the second slimming region SL2, and the upper portions of the first and second contact plugs Cx1 and Cx2 are connected to each other through wires MA. When a margin of the second slimming region SL2 is insufficient, the lines SSL, WL, and DSL extended in the first slimming region SL1 may be connected to the first row decoder 220a through the contact plug and the wire. The first page buffer unit 210a may be connected to the bit lines BL through third contact plugs Cb.

The present application relates to the connection relation between the row decoder 220 and the source lines SSL, the word lines WL, and the drain select lines DSL. The first slimming region SL1 and the second slimming region SL2 connectable with the row decoder 220 will be described in detail below.

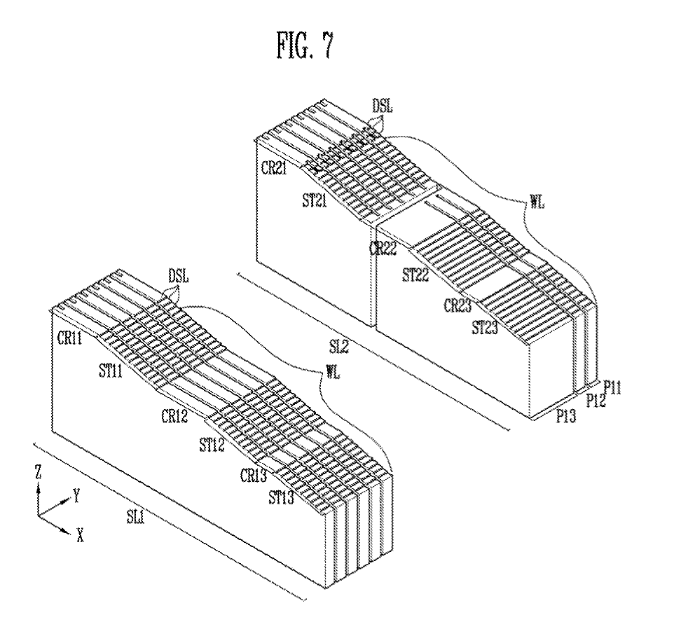

FIG. 5 is a perspective view illustrating the first slimming region of FIG. 4 and relates to the first slimming region SL1 included in the region 110a of FIG. 2.

Referring to FIG. 5, the source select lines SSL, the word lines WL, and the drain select lines DSL extended from the memory region MC are formed in a step structure in the first slimming region SL1, For example, the word lines WL may be stacked on the source lines SSL, and the drain select lines DSL may be sequentially stacked on the word lines WL in a step form. As described with reference to FIG. 4, the insulating layers are formed between the source select lines SSL, the word lines WL, and the drain select lines DSL, respectively. FIG. 5 is a perspective view schematically illustrating a structure of the source select lines SSL, the word lines WL, and the drain select lines DSL included in the first slimming region SL1. For convenience of the description, each line SSL, WL, and DSL and the insulating layers formed between the respective lines are not distinguished from each other in FIG. 5.

Referring to FIG. 5, the respective lines SSL, WL, and DSL are formed in the step structure ascending from the source select lines SSL to the drain select lines DSL. A width and a height of a step in a specific region are different from those of another region. That is, the first slimming region SL1 may include a plurality of contact regions and a so plurality of step regions, for example, the first slimming region SL1 may include an 11^{th} contact region CR11 and an 11^{th} step region ST11, a 12^{th} contact region CR12 and a 12^{th} step region ST12, and a 13^{th} contact region CR13 and a 13^{th} step region ST13. The 11^{th} contact region CR11 and an 11^{th} step region ST11 are closer to the memory region MC than the 13^{th} contact region CR13 and a 13^{th} step region ST13.

The 11^{th}, 12^{th}, and 13^{th} contact regions CR11, CR12, and CR13 may be formed with different widths and different heights depending on an etching process employed for forming the step structure of the second slimming region SL2. A structure of the second slimming region SL2 will be described with reference to FIG. 6 below. Referring to FIG. 5, a width of each of the 11^{th}, 22^{th}, and 23^{th} contact regions CR11, CR12, and CR13 is larger than a width of each of the 11^{th}, 12^{th}, and 13^{th} step regions ST11, ST12, and ST13. Here, the width of each region means a length measured along the X-direction, Further, a height of each of the 12^{th} and 13^{th} contact regions CR12 and CR13 is larger than a height of each of the 12^{th} and 13^{th} step regions ST12 and ST13. Here, the height of each region means a height measured along the Z-direction.

FIG. 6 is a perspective view illustrating the second slimming region of FIG. 4, and relates to the second slimming region SL2 included in the region 110a of FIG. 2.

Referring to FIG. 6, the source select lines SSL, the word lines WL, and the drain select lines DSL extended from the memory region MC are formed in a step structure in the first slimming region SL1. For example, the word lines WL may be stacked on the source lines SSL, and the drain select lines DSL may be sequentially stacked on the word lines WL in a step form. As described with reference to FIG. 4, the insulating layers are formed between the source select lines SSL, the word lines WL, and the drain select lines DSL, respectively. However, FIG. 6 is a perspective view schematically illustrating a structure of the source select lines SSL, the word lines WL, and the drain select lines DSL included in the second slimming region SL2. Thus, for convenience of the description, the insulating layers formed between the respective lines are not shown in FIG. 6.

Referring back to FIG. 6, the respective lines SSL, WL, and DSL are formed in the step structure ascending from the source select lines SSL to the drain select lines DSL. A width and a height of a step in a specific region are different from those of another region. That is, the width and height of the step are not uniform. The specific region may have a step in a vertical direction to the step direction. That is, the second slimming region SL2 may include the plurality of contact regions and the plurality of step regions, and steps may be generated between two neighboring contact regions.

For example, the second slimming region SL2 may include a 21^{st} contact region CR21, a 21^{st} step region ST21, a 22^{nd} contact region CR22, a 22^{nd} step region ST22, a 23^{rd} contact region CR23, and a 23^{rd} step region ST23 sequentially defined in the X-direction and in the memory region MC, and include a 11^{th} pad region P11, a 12^{th} pad region P12, and a 13^{th} pad region P13 sequentially defined in the Y-direction orthogonal to the X-direction. The 11^{th} pad region P11, the 12^{th} pad region P12, and the 13^{th} pad region P13 overlap the 21^{st} step region ST21, the 22^{nd} contact region CR22, the 22^{nd} step region ST22, the 23^{rd} contact region CR23, and the 23^{rd} step region ST23 within the second sliming region SL2.

The 12^{th} pad region P12 overlapping the 22^{nd} step region ST22 and the 23^{rd} contact region CR23 has a smaller height than that of the 11^{th} pad region P11 overlapping the 22^{nd} step region ST22 and the 23^{rd} contact region CR23, respectively. The 13^{th} pad region P13 overlapping the 22^{nd} step region ST22 and the 23^{rd} contact region CR23 has a smaller height than that of the 12^{th} pad region P12 overlapping the 22^{nd} step region ST22 and the 23^{rd} contact region CR23, respectively.

Particularly, the uppermost word lines WL included in the 22^{nd} step region ST22 and the 12^{th} pad region P12 is located at a lower level than a word line located at the lowermost word line WL included in the 22^{nd} step region ST22 and the 11^{th} pad region P11. Further, the uppermost word lines WL included in the 22^{nd} step region ST22 and the 13^{th} pad region P13 are located at a lower level than the lowermost word lines WL included in the 22^{nd} step region ST22 and the 12^{th} pad region P12.

The step between the 11^{th} pad region P11 and the 12^{th} pad region P12 in the 22^{nd} step region ST22 is the same as the step between the 11^{th} pad region P11 and the 12^{th} pad region P12 in the 23^{rd} contact region CR23. The step between the 12^{th} pad region P12 and the 13^{th} pad region P13 in the 22^{nd} step region ST22 is the same as the step between the 12^{th} pad region P12 and the 13^{th} pad region P13 in the 23^{rd} contact region CR23. A height difference H1 between the 22^{nd} contact region CR22 and the 22^{nd} step region ST22 in the 13^{th} pad region P13 is the same as a sum of (i) a height difference between the uppermost word line and the lowermost word line WL included in the region in which the 11^{th} pad region P11 and the 22^{nd} step region ST22 overlap each other (ii) a height difference between the uppermost word line and the lowermost word line WL included in the region in which the 12^{th} pad region P12 and the 22^{nd} step region ST22 overlap each other.

The steps between each of the word lines WL formed in the 11^{th} pad region P11, the 12^{th} pad region P12, and the 13^{th} pad region P13 in the 23^{rd} step region ST23 are the same steps between each of the word lines WL formed in the 11^{th} pad region P11, the 12^{th} pad region P12, and the 13^{th} pad region P13 in the 22^{nd} step region ST22.

Further, the uppermost word line WL included in the region, in which the 23^{rd} step region ST23 and the 11^{th} pad region P11 overlap each other, is located at a lower level than the lowermost word line WL included in the region, in which the 22^{nd} step region ST22 and the 13^{th} pad region P13 overlap each other. The uppermost word line WL included in the region, in which the 23^{rd} step region ST23 and the 12^{th} pad region P12 overlap each other, is located at a lower level than the lowermost word lines WL included in the region in which the 23^{rd} step so region ST23 and the 11^{th} pad region P11 overlap each other. The uppermost word line WL included in the region, In which the 23^{rd} step region ST23 and the 13^{th} pad region P13 overlap each other, is located at a lower level than the lowermost word line WL included in the region, in which the 23^{rd} step region ST23 and the 12^{th} pad region P12 overlap each other.

The source select lines SSL may include a plurality of lines stacked from the lowermost end of the region in which the 23^{rd} step region ST23 and the 13^{th} pad region P13 overlap. The word lines WL may be stacked from the upper portions of the source select lines SSL to the 21^{st} step region ST21. The drain select lines DSL may include a plurality of lines stacked from the upper portions to the uppermost word lines WL included in the 21^{st} step ST21.

As described above, since the step is formed in the word lines WL for each pad region within the step region, more word lines WL are exposed within the same step region. The contact plugs may be connected to the plurality of word lines. Accordingly, it is possible to prevent the first and second slimming regions SL1 and SL2 from increasing in the X-direction, thereby increasing a degree of integration of the semiconductor device.

A method of manufacturing the first and second slimming regions SL1 and SL2 shown in FIGS. 5 and 6 will be described below.

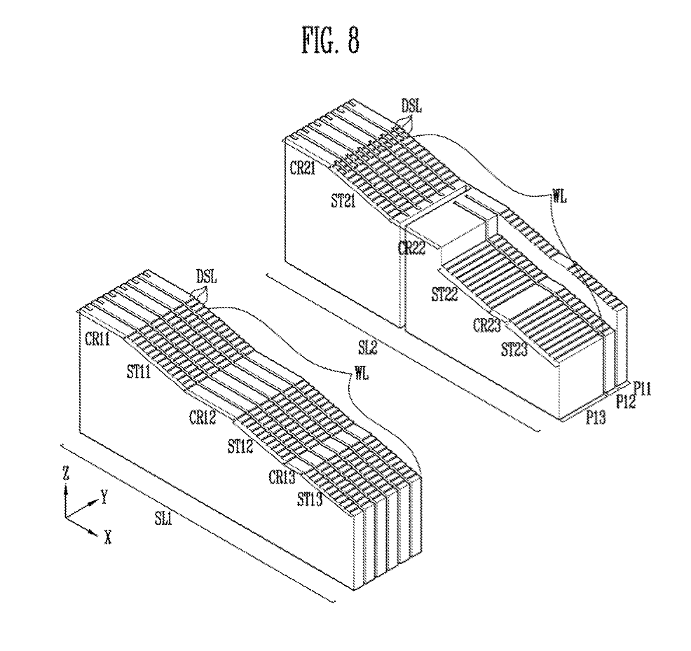

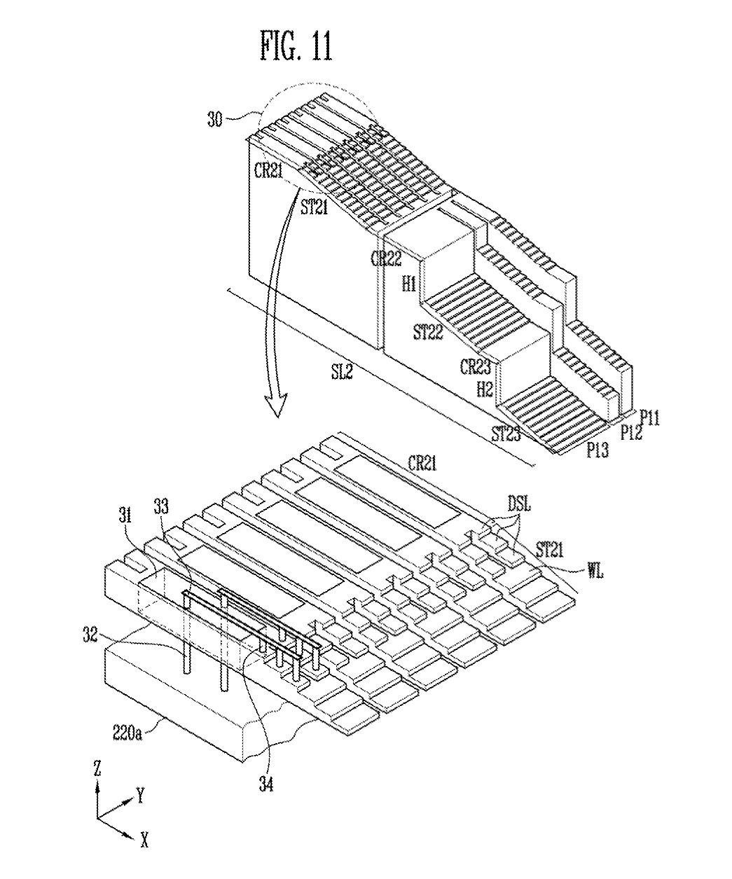

FIGS. 7 and 10 are perspective views for illustrating a method of forming the first slimming region and the second slimming region according to an exemplary embodiment of the present application.

Referring to FIG. 7, a slimming process of etching gate lines extended from the memory region MC to the first slimming region SL1 and the second slimming region SL2, respectively, in a step form or a pad form, is performed. For example, in the first slimming region SL1 and the second slimming region SL2, the drain select lines DSL and some word lines WL are formed in the 11^{th} step region ST11 and the 21^{st} step region ST21 by etching the gate lines of the remaining regions ST11, ST21, CR12, CR22, ST12, ST22, CR13, CR23, ST13, and ST23 except for the 11^{th} contact region CR11 and the 21^{st} contact region CR21 in a step form.

Some word lines WL are formed in the 12^{th} step region ST12 and the 22^{nd} step region ST22 by etching the gate lines in the remaining regions except for the 11^{th} contact region CR11, the 21^{st} contact region CR21, the 11^{th} step region ST11, the 21^{st} step region ST21, the 12^{th} contact region CR12, and the 22^{nd} contact region CR22 in a step form.

Next, some word fines WL are formed in the 13^{th} step region ST13 and the 23^{rd} step region ST23 by etching the gate lines of the 13^{th} step region ST13 and the 23^{rd} step region ST23 in a step form.

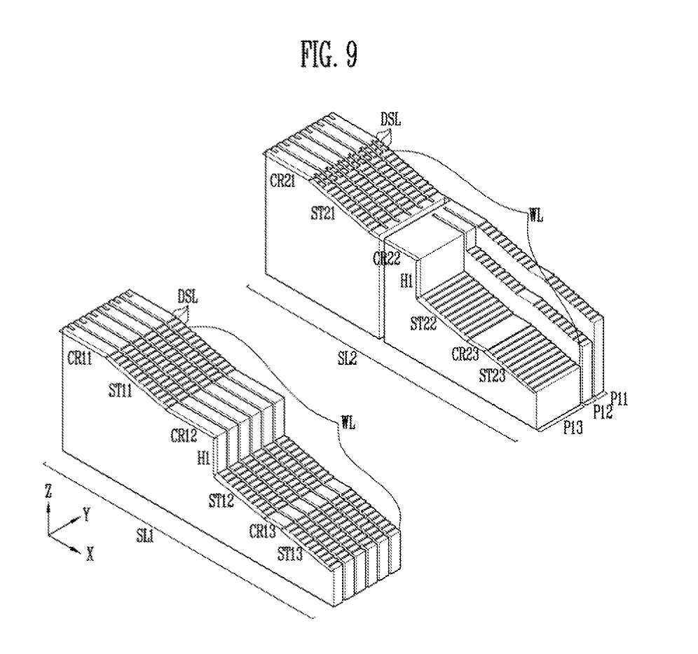

Referring to FIG. 8, heights of the lines are decreased by etching the word lines included in the regions in which the 22^{nd} step region ST22, the 23^{rd} contact region CR23, and the 23^{rd} step region ST23 of the second slimming region SL2 overlap the 12^{th} pad region P12 and the 13^{th} pad region P13. The etching process is performed until a word line adjacent to a lower portion of the lowermost word line among the word lines WL included in the region, in which the 22^{nd} step region ST22 and the 11^{st} pad region P11 overlap each other.

The word lines included in the regions in which the 22^{nd} step region ST22, the 23^{rd} contact region CR23, and the 23^{rd} step region ST23 overlap the 12^{th} and 13^{th} pad regions P12 and P13, so that the word lines included in the regions, in which the 22^{nd} step region ST22 overlaps the 12^{th} and 13^{th} pad regions P12 and P13, are etched in a step form.

Next, the word lines WL included in the regions, in which the 23^{rd} step region ST23 overlaps the 12^{th} and 13^{th} pad regions P12 and P13, are etched in a step form.

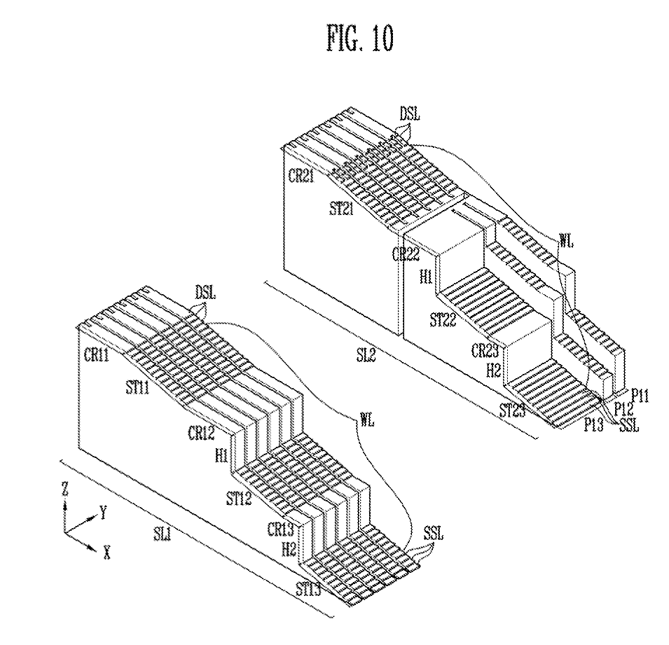

Referring to FIG. 9, a height of the region is decreased by etching the word lines WL Included in the regions, in which the 22^{nd} step region ST22, the 23^{rd} contact region CR23, and the 23^{rd} step region ST23 of the second slimming region SL2 overlap the 13^{th} pad region P13, and the word lines WL included in the 12^{th} step region ST12, the 13^{th} contact region CR13, and the 13^{th} step region ST13 of the first slimming region SL1. For example, the etching process is performed until the word line adjacent to the portion just under the word line located at the lowermost end of the 12^{th} pad region P12 is exposed in the region, in which the 13^{th} pad region P13 overlaps the 22^{nd} step region ST22.

Referring to FIG. 10, heights of the lines are decreased by etching the word lines WL and the source select lines SSL included in the 13^{th} step region ST13 of the first slimming region SL1 and the 23^{rd} step region ST21 of the second slimming region SL2. The etching process is simultaneously performed on the first slimming region SL1 and the second slimming region SL2, so that a height difference H2 between the word line of the 13^{th} contact region CR13 and the word line located at the uppermost end of the 13^{th} step region ST13 is the same as a height difference H2 between the word line of the 23^{rd} contact region CR23 and the word line located at the uppermost end of the 23^{rd} step region ST23. Although not Illustrated, a contact region may be further included in the X-direction of the 13^{th} step region ST13 or the 23^{rd} step region ST23.

By the aforementioned etching process, all of the drain select lines DSL, the word lines WL, and the source select lines SSL may be exposed.

Next, a structure of a connection of the drain select lines, the word lines WL, and the source select lines SSL to the first row decoder 220a will be described.

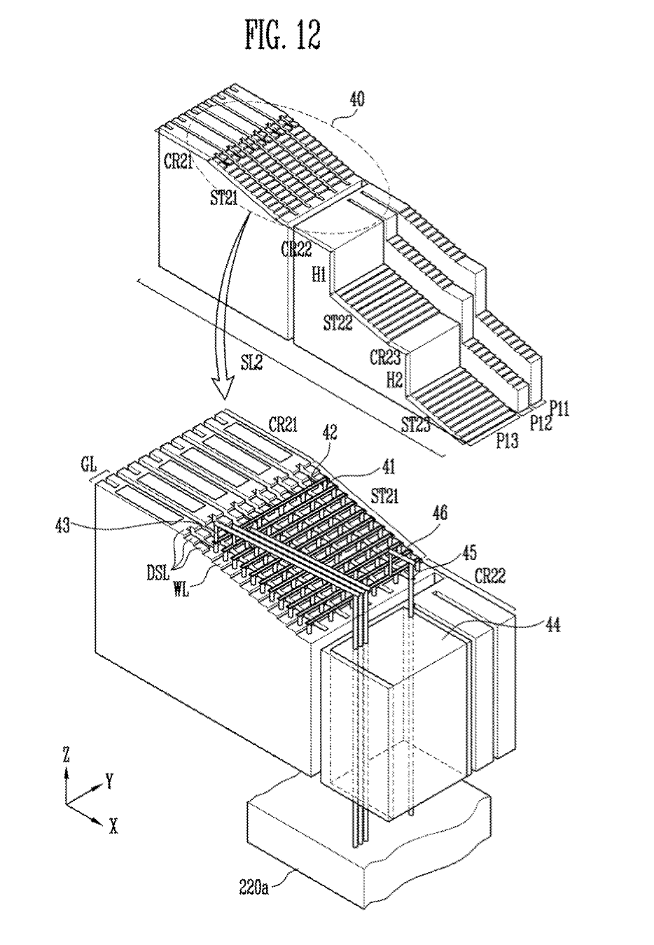

FIG. 11 is a perspective view illustrating a connection relation between the drain select lines and the row decoder according to the exemplary embodiment of the present application.

Referring to FIG. 11, the drain select lines DSL may be connected to the first row decoder 220a in the second slimming region SL2. According to an enlarged view of a portion 30 of the 21^{st} contact region CR21 and the 21^{st} step region ST21 of the second slimming region SL2, first blocking layers 31 are formed within the 21^{st} contact region CR21. First contact plugs 32 positioned vertically that is, in a Y-direction passing through the first blocking layers 31 are formed. The first blocking layers 31 have smaller areas than a flat area of the 21^{st} contact area CR21, and have heights the same as the distance between lines located at the uppermost end and lines located at the lowermost end among the lines formed in the 21^{st} contact regions CR21. The first blocking layers 31 may be formed of an insulating material such as an oxidization layer.

For example, the height of the first blocking layer 31 may be the same as the distance from an upper surface of the drain select line DSL formed at the uppermost end of the memory block to a lower surface of the line formed at the lowermost end of the memory block. The first contact plugs 32 are connected to the first row decoder 220a located at the lower portion of the memory block, and protrude from upper portions of the dram select lines DSL at the lowermost end. Second contact plugs 34 are formed on the drain select lines DSL, respectively. First wires 33 are formed on the first and second contact plugs 31 and 34.

The first and second contact plugs 32 and 34 and the first wires are formed of conductive layers. Accordingly, the first row decoder 220a, the first contact plugs 32, the first wires 33, the second contact plugs 34, and the drain select lines DSL are connected to one another. FIG. 11 illustrates the configuration in which some of the drain select lines DSL are connected to the first row decoder 220a. However, this is for so convenience of the description. In another embodiment, all of the drain select lines DSL may be substantially connected to the first row decoder 220a just as the aforementioned structure.

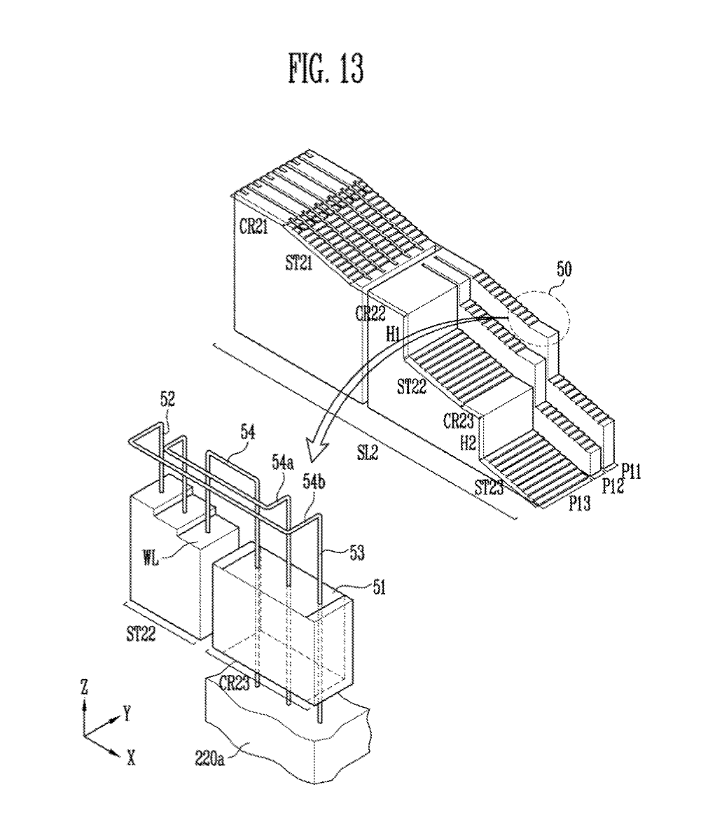

FIGS. 12 and 13 are perspective views illustrating a connection relation between the word lines and the row decoder according to an exemplary embodiment of the present application.

FIG. 12 is a perspective view for describing a connection configuration of the word lines WL and the first row decoder 220a through the 13^{th} pad region P13 having a relative large area among the 11^{th} pad region P11, the 12^{th} pad region P12, and the 13^{th} pad region P13. FIG. 13 is a perspective view for illustrating a connection configuration of the word lines WL and the first row decoder 220a through the 11^{th} or 12^{th} pad region P11 or P12.

Referring to FIG. 12, the word lines WL may be connected to the first row decoder 220a in the second slimming region SL2. According to an enlarged view of a portion 40 of the 21^{st} step region ST21 and the 22^{nd} contact region CR22 of the second slimming region, third contact plugs 41 are formed on the word lines WL, and the third contact plugs 41 formed on the word lines WL on the same layer are connected to each other through second wires 42. For example, the third contact plugs 41 may be formed with the same height, and are formed on the word lines WL divided in the unit of the cell string, respectively. The third contact plugs 41 and the second wires 42 are formed of conductive layers. Accordingly, the word lines WL formed on the same layer may so be electrically connected to each other, and the word lines WL formed on different layers may not be electrically connected to each other. Fourth contact plugs 43 may be formed on the second wires 42, respectively. For example, one fourth contact plug 43 may be formed on the second wire 42.

Second blocking layers 44 are formed within the 22^{nd} contact region CR22, and fifth contact plugs 45 are formed vertically that is, in a Y-direction passing through the second blocking layers 44. The second blocking layers 44 have smaller areas than a flat area of the 22^{nd} contact area CR22, and have heights the same as the distance, between lines at the uppermost end and lines at the lowermost end among the lines formed in the 22^{nd} contact regions CR22. The 22^{nd} contact area CR22 may be formed of an insulating material, such as an oxidization layer.

For example, a height of the second blocking layer 44 may be the same as the distance measured from an upper surface of the gate line GL located at the uppermost end of the 22^{nd} contact region CR22 of the memory block to a lower surface of the gate line GL located at the lowermost end of the memory block. Accordingly, the second blocking layers 44 are exposed on the 22^{nd} contact area CR22, Lower portions of the fifth contact plugs 45 are connected to the first row decoder 220a located at the lower portion of the memory block, and upper portions thereof protrude from upper portions of the second blocking layers 44.

Upper portions of the fourth contact plugs 43 and upper portions of the fifth contact plugs 45 are connected to each other through third wires 48. The fifth contact plugs 45 and the third wires 46 are formed of conductive layers. Accordingly, when an operation voltage is transmitted to the fifth contact plugs 45 from the first row decoder 220a, the operation voltages may be transmitted up to the word lines WL through the third wires 48, the fourth contact plugs 43, the second wires 42, and the third contact plugs 41.

FIG. 12 illustrates the configuration, in which the word lines included in some pages are connected to the first row decoder 220a, but this is for convenience of the description. In another embodiment, the plurality of word lines included in the 21^{st} step region ST21 may be connected to the first row decoder 220a just as the aforementioned structure.

Referring to FIG. 13, according to an enlarged view of a portion of the 22^{nd} step region ST22 and the 23^{rd} contact region CR23 overlapping the 11^{th} pad region P11 in the second slimming region SL2, the 11^{th} pad region P11 has the same width as a width of the word lines WL divided in the unit of the cell string. Accordingly, one word line is formed on each layer in the region, in which the 22^{nd} step region ST22 overlaps the 11^{th} pad region P11. Sixth contact plugs 52 may be formed on the word lines WL, respectively, in the region, in which the 22^{nd} step region ST22 overlaps the 11^{th} pad region P11.

A third blocking layer 51 is formed inside the word lines formed in the 23^{rd} contact area CR23, The third blocking layer 51 has a smaller fiat area than a flat area of the 23^{rd} contact area CR23, and has a height so from the uppermost end to the lowermost end of the 23^{rd} contact region CR23. The third blocking layer 51 may be formed of an insulating material, such as an oxidization layer.

FIG. 13 illustrates a cross-section of a part of the 23^{rd} contact area CR23. The third blocking layer 51 is formed inside the word lines formed in the region, in which the 23^{rd} contact area CR23 overlaps the 11^{th} pad region P11. That is, the third blocking layer 51 may be formed in a structure having a smaller flat area than that of the word line and the same height as that of the word line so as to prevent some of the word lines formed in the region, in which the 23^{rd} contact area CR23 overlaps the 11^{th} pad region P11, from being cut off to each other.

Seventh contact plugs 53 may be formed so as to pass through the third blocking layer 51 in the vertical direction that is, in a Y-direction, and formed of a conductive layer. Lower portions of the seventh contact plugs 53 are connected to the first row decoder 220a located at a lower portion of the third blocking layer 51, and upper portions thereof protrude from an upper portion of the third blocking layer 51. The sixth contact plugs 52 and the seventh contact plugs 53 may be connected through the fourth wires 54. When the width of the 11^{th} pad region P1 is small, the fourth wires 54 may be horizontally arranged in the Y-direction. Fifth wires 54a and 54b for connecting the fourth wires 54 and the sixth or seventh contact plugs 52 and 53 may be further formed.

As described with reference to FIGS. 12 and 13, the word lines included in the step regions may be connected to the contact plugs, respectively, by forming the blocking layers in the contact regions, and forming the contact plugs vertically passing through the blocking layers. The operation voltages output from the row decoder may be transmitted to the word lines by connecting the contact plugs vertically passing the blocking layers to the row decoder located at the lower portion of the memory block. Further, in FIGS. 12 and 13, some step regions, contact regions, and pad regions have been described as the exemplary embodiment, but all of the word lines WL may be connected to the row decoder by applying the aforementioned structure.

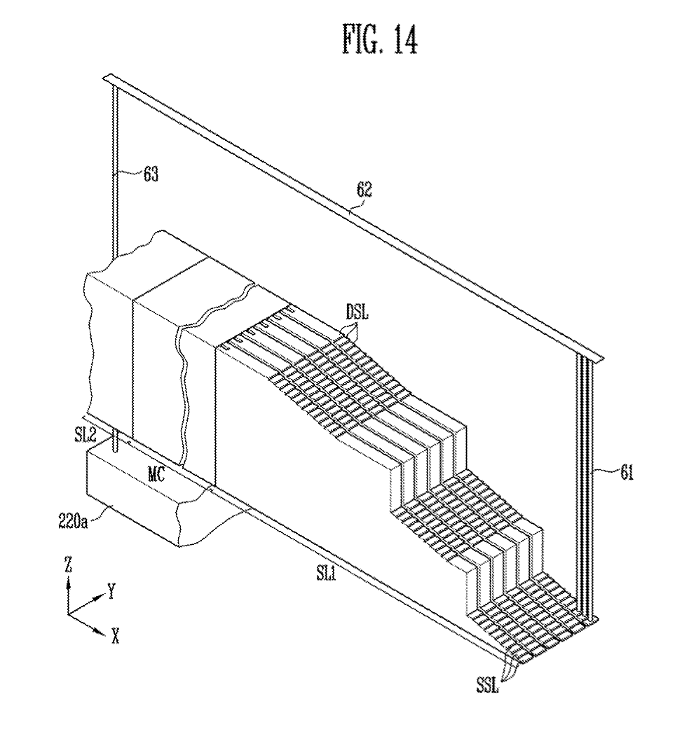

FIG. 14 is a perspective view illustrating a connection relation between the source select tines and the row decoder according to the exemplary embodiment of the present invention.

Referring to FIG. 14, the contact plugs for connecting the source select lines SSL to the first row decoder 220a may be formed in the first slimming region SL1 or the second slimming region SL2. However, when the contact plugs for connecting the drain select lines DSL and the word lines WL to the first row decoder 220a are formed in the second slimming region SL2, a margin for forming the contact plugs for connecting the source select lines SSL to the first row decoder 220a in the second slimming region SL2 may be insufficient.

In this case, as illustrated in FIG. 14, the contact plugs for connecting the source select lines SSL to the first row decoder 220a may be formed in the first slimming region SL1. For example, eighth contact plugs 61 may be formed on the source select lines SSL exposed in the first slimming region SL1, and ninth contact plugs 63 may be formed on the first row decoder 220a. Sixth wires 62 for connecting the eighth and ninth contact plugs 61 and 63 with each other may be formed. In order for the sixth wires 62 to be formed over the first slimming region SL1, the memory region MC, and the second slimming region SL2, the sixth wires 62 may be formed at a higher location than the drain select lines DSL at the uppermost end.

The source select lines SSL, the word lines WL, and the drain select lines DSL included in the remaining memory blocks, except for the memory blocks connected to the first row decoder 220a, may be connected to the second row decoder 220b as described in the aforementioned structure.

FIG. 15 is a block diagram illustrating a solid state drive including the semiconductor device according to an exemplary embodiment of the present application. Referring to FIG. 15, a drive device 2000 includes a host 2100 and a Solid Disk Drive (SSD) 2200. The SSD 2200 includes an SSD controller 2210, a buffer memory 2220, and the semiconductor device 1000.

The SSD controller 2210 physically connects the host 2100 and the SSD 2200, That is, the SSD controller 2210 provides interfacing with the SSD 2200 in accordance with a bus format of the host 2100. Particularly, the SSD controller 2210 decodes a command provided from the host 2100. The SSD controller 2210 accesses the semiconductor device 1000 according to a result of the decoding. The bus format of the host 2100 may include a Universal Serial Bus (USB), a Small Computer System Interface (SCSI), PCI process, ATA, Parallel ATA (RATA), Serial ATA (SATA), or a Serial Attached SCSI (SCSI).

Program data provided from the host 2100 and data read from the semiconductor device 1000 is temporarily stored in the buffer memory 2220. When data existing in the semiconductor device 1000 is cached when a read request is made from the host 2100, the buffer memory 2200 supports a cache function for directly providing the cached data to the host 2100. In general, a data transmission speed by the bus format for example, SATA or SAS of the host 2100 may be faster than a transmission speed of a memory channel. That is, when an interface speed of the host 2100 is faster than the transmission speed of the memory channel of the SSD 2200, it is possible to minimize degradation of performance generated due to a speed difference by providing the buffer memory 2220 with a large capacity. The buffer memory 2220 may be provided as a synchronous DRAM so that the SSD 2200 used as an auxiliary memory device with large capacity provides sufficient buffering.

The semiconductor device 1000 is provided as a storage medium of the SSD 2200, For example, the semiconductor device 1000 may be provided as a non-volatile memory device having large capacity storage performance as described with reference to FIG. 1, particularly, a NAND-type flash memory among the non-volatile memory devices.

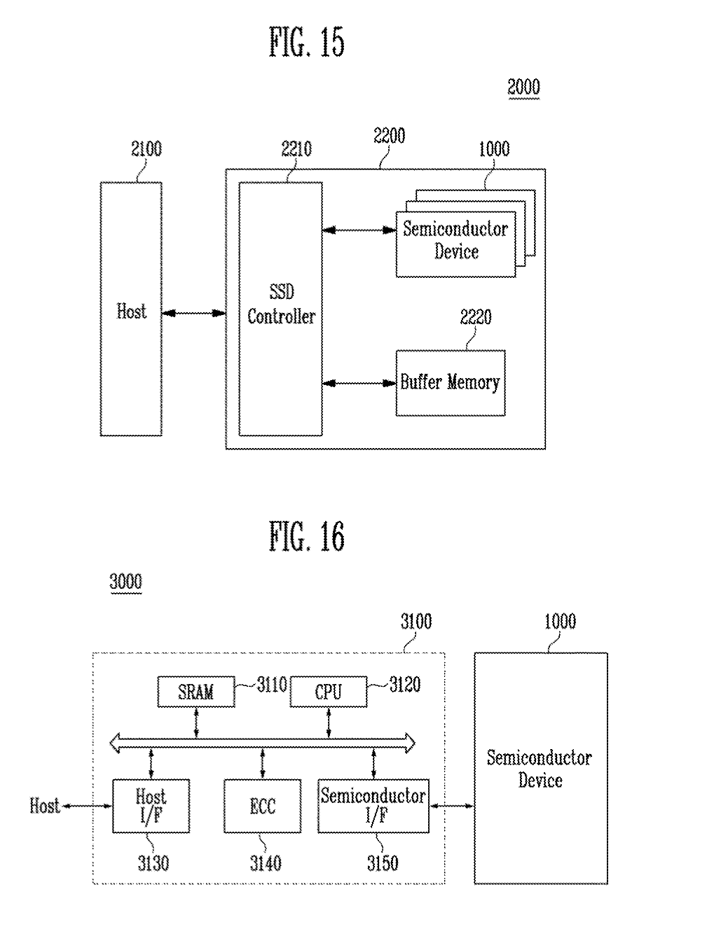

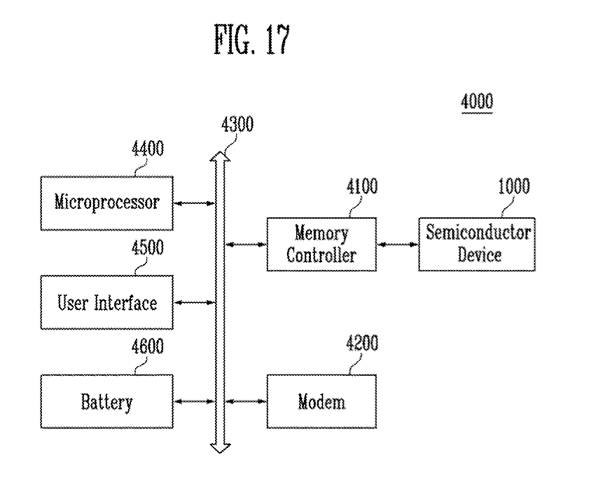

FIG. 16 is a block diagram illustrating a memory system including the semiconductor device according to the exemplary embodiment of the present application. Referring to FIG. 16, a memory system 3000 according to the present application may include a memory controller 3100 and the semiconductor device 1000. The semiconductor device 1000 may have a configuration substantially the same as that of FIG. 1, so that a detailed description of the semiconductor device 1000 will be omitted.

The memory controller 3100 may be configured to control the semiconductor device 1000. The SRAM 3110 may be used as a working memory of a CPU 3120. A host interface (Host I/F) 3130 may include a data exchange protocol of a host connected with a memory system 3000. An error correction circuit (ECC) 3140 provided in the memory controller 3100 may detect and correct an error included in data read from the semiconductor device 1000. A semiconductor interface for example, semiconductor I/F 3150 may interface with the semiconductor device 1000. The CPU 3120 may perform a control operation for exchanging data of the memory controller 3100. Further, although not illustrated in FIG. 16, the memory system 3000 may further Include a ROM (not illustrated) for storing code data for interfacing with the host. The memory system 3000 according to the present invention may be applied to one of a computer, a portable terminal, a Ultra Mobile PC (UMPC), a work station, a net-book computer, a PDA, a portable computer, a web tablet PC, a wireless phone, a mobile phone, a smart phone, a digital camera, a digital audio recorder, a digital audio player, a digital picture recorder, a digital picture player, a digital video recorder, a digital video player, a device capable of transceiving information in a wireless environment, and various devices configuring a home network.

FIG. 17 is a diagram illustrating a schematic configuration of a computing system including the semiconductor device according to the exemplary embodiment of the present invention. Referring to FIG. 17, a computing system 4000 according to the present invention includes the semiconductor device 1000, the memory controller 4100, a modem 4200, a microprocessor 4400, and a user interface 4500 which are electrically connected to a bus 4300. In a case where the computing system 4000 according to the present invention is a mobile device, a battery 4600 for supplying an operation voltage of the computing system 4000 may be further provided. Although it is not illustrated in the drawing, the computing system 4000 according to the present invention may further include an application chipset, a Camera Image Processor (CIS), a mobile DRAM, and the like.

The semiconductor device 1000 may have a configuration substantially the same as that of FIG. 1, therefore a detailed description of the semiconductor device 1000 will be omitted. The memory controller 4100 and the semiconductor device 1000 may configure an SSD.

The semiconductor device and the memory controller according to the present invention may be embedded by using various forms of packages, For example, the semiconductor device and the memory controller according to the present application may be embedded by using packages, such as package on package (PoP), ball grid arrays (BGAs), chip scale packages (CSPs), plastic leaded chip carrier (PLCC), plastic dual in line package (PDIP), die in waffle pack, die in wafer form, chip on board (COB), ceramic dual in line package (CERDIP), plastic metric quad flat pack (MQFP), thin quad flat pack (TQFP), small outline (SOIC), shrink small outline package (SSGP), thin small outline (TSOP), thin quad flat pack (TQFP), system in package (SIP), multi-chip package (MCP), wafer-level fabricated package (WFP), and wafer-level processed stack package (WSP).

As described above, various embodiments have been disclosed in the drawings and the specification. The specific terms used herein are for purposes of illustration, and do not limit the scope of the present invention defined in the claims. Accordingly, those skilled in the art will appreciate that various modifications and other equivalent embodiments may be made without departing from the scope and spirit of the present disclosure. Therefore, the scope of the present invention will be defined by the technical spirit of the accompanying claims.

What is claimed is:

1. A three-dimensional semiconductor device, comprising:
a peripheral circuit; and
a memory cell array stacked on the peripheral circuit and including a memory region and a slimming region which are defined in a first direction,
wherein the slimming region includes contact regions and step regions alternately defined in the first direction,
wherein the slimming region further includes pad regions defined in a second direction orthogonal to the first direction,
wherein the pad regions overlap with some of the contact regions and some of the step regions,
wherein gate lines are included in the step regions and arranged in a step form in the first direction, and
wherein gate lines are included in a region, in which the contact regions, the step regions, and the pad regions overlap each other, and have steps in the second direction.

2. The three-dimensional semiconductor device of claim 1,
wherein the gate lines include source select lines, word lines, and drain select lines.

3. The three-dimensional semiconductor device of claim 2,
wherein the word lines are stacked over the source select lines, and
wherein the drain select lines are stacked over the word lines.

4. The three-dimensional semiconductor device of claim 1,
wherein only upper surfaces of gate lines located at the uppermost end among the gate lines included in the contact regions are exposed.

5. The three-dimensional semiconductor device of claim 1,
wherein gate lines formed in the region, in which the contact regions, the step regions, and the pad regions overlap each other, and formed at different levels from each other are exposed.

6. The three-dimensional semiconductor device of claim 1, further comprising:
blocking layers formed In the gate lines of the contact regions;
first contact plugs vertically passing through the blocking layers;
second contact plugs formed over the gate lines in the step regions; and
wires configured to connect upper portions of the first contact plugs with upper portions of the second contact plugs.

7. The three-dimensional semiconductor device of claim 6,
wherein the blocking layers have a smaller area than a flat area of the contact regions, and have a height from the gate lines at the uppermost end to the gate lines at the lowermost end formed in the contact regions.

8. The three-dimensional semiconductor device of claim 6, wherein the first contact plugs are connected to the wires at an upper portion of the blocking layers and connected to the peripheral circuit at a lower portion of the blocking layers.

9. The three-dimensional semiconductor device of claim 8, wherein the peripheral circuit includes a row decoder.

10. The three-dimensional semiconductor device of claim 6, wherein the second contact plugs are connected to upper portions of the gate lines included in the step regions, respectively.

11. A three-dimensional semiconductor device, comprising:
a row decoder; and
a memory cell array including source select lines, word lines, and drain select lines,
wherein the source select lines, the word lines, and the drain select lines are sequentially stacked over the row decoder,
wherein a first slimming region, a memory region, and a second slimming region are defined in the memory cell array in a first direction,
wherein the source select lines are connected to the row decoder through first contact plugs formed In the first slimming region, and
wherein the word lines and the drain select lines are connected to the row decoder through second contact plugs and third contact plugs formed in the second slimming region, respectively.

12. The three-dimensional semiconductor device of claim 11,
wherein the source select lines, the word lines, and the drain select lines are stacked in the memory region and extend to the first slimming region and the second slimming region.

13. The three-dimensional semiconductor device of claim 12,
wherein the source select lines, the word lines, and the drain select lines extended to the first slimming region have steps formed ascending from the source select lines toward the drain select lines.

14. The three-dimensional semiconductor device of claim 13,
wherein the first contact plugs are formed over the source select lines in the first slimming region and are connected to the row decoder through a first wire crossing upper portions of the first slimming region, the memory region, and the second slimming region, and
wherein a fourth contact plug is connected to a lower portion of the first wire in the second slimming region.

15. The three-dimensional semiconductor device of claim 12,
wherein the second slimming region includes step regions and contact regions alternately defined in the first direction, and
wherein the second slimming region further includes pad regions overlapping some of the step regions and some of the contact regions in a second direction orthogonal to the first direction.

16. The three-dimensional semiconductor device of claim 15,
wherein, in the second slimming region, the second contact plugs are formed over the word lines and are connected to fifth contact plugs, and
wherein the fifth contact plugs are connected to the row decoder in the contact regions.

17. The three-dimensional semiconductor device of claim 16,
wherein the fifth contact plugs are formed inside the contact regions, and vertically pass through first blocking layers, and
wherein the first blocking layers are electrically isolated from the source select lines, the word lines, and the drain select lines.

18. The three-dimensional semiconductor device of claim 15,
wherein, in the second slimming region, the third contact plugs are formed over the drain select lines and are connected to sixth contact plugs, and
wherein the sixth contact plugs are connected to the row decoder in the contact regions.

19. The three-dimensional semiconductor device of claim 18,
wherein the sixth contact plugs are formed inside the contact regions, and vertically pass through second blocking layers, and
wherein the second blocking layers are electrically isolated from the source select lines, the word lines, and the drain select lines.

20. The three-dimensional semiconductor device of claim 15,
wherein, in the second slimming region, some of the word lines and the source select lines included in the regions, in which the step regions, the contact regions, and the pad regions overlap one another, have steps in the second direction.
